(19) United States
(12) Patent Application Publication
(10) Pub. No.: US 2026/0106619 A1
(43) Pub. Date: Apr. 16, 2026

(54) Crossbar Switch Circuits And Methods In Integrated Circuits

(71) Applicant: Altera Corporation, San Jose, CA (US)

(72) Inventors: Martin Langhammer, Salisbury (GB); Ilya Ganusov, San Jose, CA (US); Gregg Baeckler, San Jose, CA (US)

(73) Assignee: Altera Corporation, San Jose, CA (US)

(21) Appl. No.: 18/915,782

(22) Filed: Oct. 15, 2024

(51) Int. Cl. H03K 19/17728

(52) U.S. Cl. CPC H03K 19/17728

(57) ABSTRACT

A configurable integrated circuit includes first logic circuits, second logic circuits, and a crossbar switch circuit. The crossbar switch circuit includes multiplexer circuits and input busses coupled to the multiplexer circuits. The inputs of each of the multiplexer circuits are coupled to each of the input busses. The configurable integrated circuit is configurable to provide input signals generated by the first logic circuits to the inputs of each of the multiplexer circuits through the input busses. The multiplexer circuits are configurable to provide values of the input signals that are received through the input busses to the second logic circuits.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that illustrates an example of a crossbar switch circuit.

FIG. 2 is a diagram that illustrates an example of a portion of a configurable integrated circuit (IC) that includes 3 crossbar switch circuits.

FIG. 3 is a diagram that illustrates another example of a portion of a configurable integrated circuit (IC) that includes 2 crossbar switch circuits.

FIG. 4 is a diagram that illustrates an example of a crossbar switch circuit that can be used to implement redundancy for a row or column of configurable logic circuits in a configurable integrated circuit (IC).

FIG. 5 is a diagram that illustrates an example of a selection modification circuit.

FIGS. 6A-6B illustrate examples of multiplexer circuits that can be implemented by a crossbar switch circuit using the techniques disclosed herein.

FIGS. 7A-7B illustrate additional examples of multiplexer circuits that can be implemented by a crossbar switch circuit using the techniques disclosed herein.

FIG. 8 is a diagram of an illustrative example of a configurable integrated circuit (IC).

FIG. 9A illustrates a block diagram of a system that can be used to implement a circuit design to be programmed into a programmable logic device using design software.

FIG. 9B is a diagram that depicts an example of a programmable logic device that includes fabric dies and base dies that are coupled to one another via microbumps.

FIG. 10 is a block diagram illustrating a computing system configured to implement one or more aspects of the embodiments described herein.

### DETAILED DESCRIPTION

Multiplexer circuits effectively account for up to half of many field programmable gate array (FPGA) circuit designs. Wide, parallel busses that are used by many of the FPGA circuit designs in some applications place a large strain on logic circuit and routing resources, which causes resource limitations as well as fitting problems.

According to some examples disclosed herein, an integrated circuit (IC), such as a configurable IC (e.g., an FPGA), includes one or more crossbar switch circuits embedded in a fabric of configurable logic circuits. The IC includes redundant rows or columns of configurable logic circuits that can be enabled using select modification circuits. General purpose multiplexer circuits can be synthesized and coupled to the crossbar switch circuits. The crossbar switch circuits may add a small amount of additional die area to the IC, but the crossbar switch circuits can reduce the amount of configurable logic circuits used by a circuit design by up to 50% in some applications. In addition, the crossbar switch circuits can make a circuit design for the IC close timing at a significantly higher speed, and can allow the IC to operate at a significantly lower power consumption.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

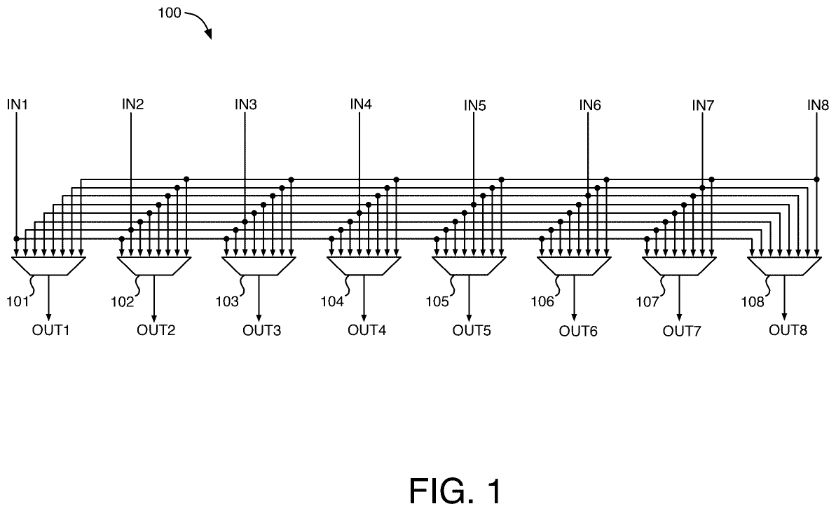

FIG. 1 is a diagram that illustrates an example of a crossbar switch circuit 100. The crossbar switch circuit 100 can be fabricated in any type of integrated circuit (IC), such as a configurable IC (e.g., a field programmable gate array (FPGA) or programmable logic device (PLD)), a microprocessor IC, a graphics processing unit IC, a memory IC, an application specific IC, a transceiver IC, etc. In the examples disclosed below, crossbar switch circuit 100 is described in the context of a configurable IC, such as an FPGA or PLD.

The crossbar switch circuit 100 of Figure (FIG.) 1 includes 8 multiplexer circuits 101-108 and 8 input busses. Each of the 8 input busses is an 8-bit bus that includes 8 parallel conductors (e.g., wires) for transmitting the 8-bits in parallel. In a configurable IC, if the input busses are implemented as N-bit busses, the input busses may be configured as smaller busses that each transmit less than N bits, and the unused conductors in the input busses are not coupled to any circuitry, nor tied to a fixed voltage level. Each of the 8 input busses is coupled through hardwired non-configurable conductors to an input of each of the 8 multiplexer circuits 101-108, as shown in FIG. 1. The 8 input busses transmit all 8 input signals IN1, IN2, IN3, IN4, IN5, IN6, IN7, and IN8 to the 8 inputs of each of the 8 multiplexer circuits 101, 102, 103, 104, 105, 106, 107, and 108, as shown in FIG. 1. The 8 multiplexer circuits 101, 102, 103, 104, 105, 106, 107, and 108 generate 8 output signals OUT1, OUT2, OUT3, OUT4, OUT5, OUT6, OUT7, and OUT8, respectively, at their outputs. Couplings between conductors (wires) in the input busses are shown by dots in FIG. 1. Although 8 multiplexer circuits 101-108 and 8 input busses are shown in the example of FIG. 1, it should be understood that crossbar switch circuits designed according to the principles disclosed herein can include any number M of multiplexer circuits and a corresponding number M of input busses.

The multiplexer circuits 101-108 are configurable by select signals (not shown in FIG. 1) to provide the values of a selected combination of the input signals IN1-IN8 to the output signals OUT1-OUT8. Each of the multiplexer circuits 101-108 can be coupled to a selection circuit (not shown in FIG. 1) that generates a select signal for configuring the multiplexer circuit to provide the value of one of the input signals IN1-IN8 to the output signal (i.e., one of signals OUT1-OUT8) of the multiplexer circuit.

In some applications of the crossbar switch circuit 100, there may be collisions caused by two of the input signals IN1-IN8 being multiplexed to the same output signal (i.e., one of output signals OUT1-OUT8). If such a collision is detected, an arbitration circuit (not shown) can be used to resolve the collision by spreading the selection of the two or more input signals IN1-IN8 to the same output signal (i.e., one of output signals OUT1-OUT8) over multiple cycles of a clock signal. In the crossbar switch circuit 100 of FIG. 1, most of the IC die area and routing is consumed by the multiplexer circuits 101-108.

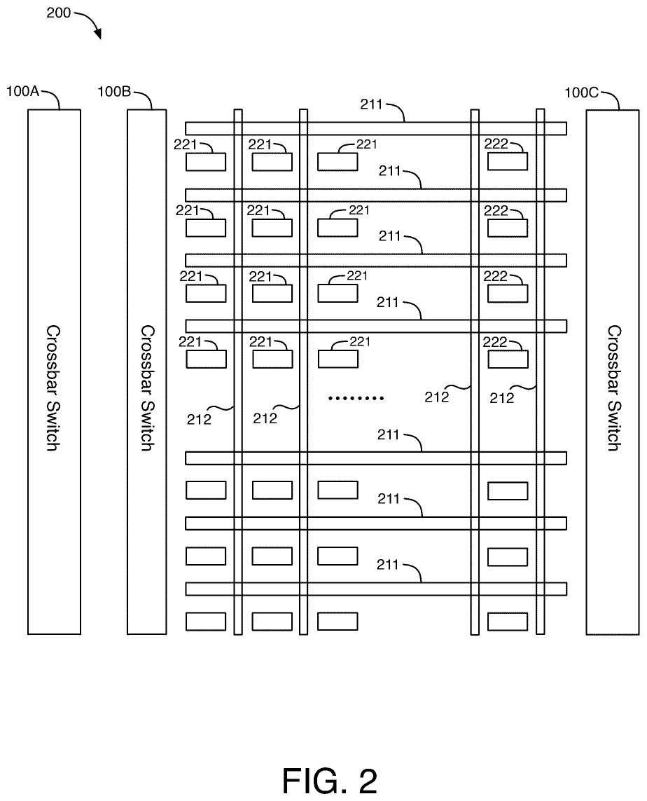

FIG. 2 is a diagram that illustrates an example of a portion 200 of a configurable integrated circuit (IC) that includes 3 crossbar switch circuits 100A, 100B, and 100C. The portion 200 (e.g., sector or region) of the configurable IC shown in FIG. 2 includes configurable logic circuits 221 (shown in 3 columns as an example), memory circuits 222 (shown in 1 column as an example), horizontal routing channels 211, and vertical routing channels 212. Each of the crossbar switch circuits 100A, 100B, and 100C shown in FIG. 2 can, as examples, include an instance of the crossbar switch circuit 100 of FIG. 1 or a crossbar switch circuit with any number of multiplexer circuits.

The crossbar switch circuits 100A, 100B, and 100C can transmit signals between configurable logic circuits 221, multi-port memory circuits 222, and other routing in the IC, such as horizontal routing channels 211 and vertical routing channels 212. For example, the crossbar switch circuits 100A, 100B, and 100C can be coupled through conductors (not shown) to the horizontal routing channels 211 to transmit signals between the configurable logic circuits 221 and the multi-port memory circuits 222.

The multi-port memory circuits 222 can be used in many circuit designs for configurable integrated circuits (ICs), such as the core memory circuits for parallel processors (e.g., vector processors). In the example shown in FIG. 2, a first one of the crossbar switch circuits 100A, 100B, and 100C can be used for the data input to the memory circuits 222, a second one of the crossbar switch circuits 100A, 100B, and 100C can be used for addressing to the memory circuits 222, and a third one of the crossbar switch circuits 100A, 100B, and 100C can be used for the data output from the memory circuits 222.

In some exemplary implementations, all 3 of the crossbar switch circuits 100A, 100B, and 100C can be implemented as embedded blocks. According to various exemplary implementations, 1 or 2 of the crossbar switch circuits 100A, 100B, and 100C can be implemented as embedded blocks with hard logic, and the remaining 1 or 2 crossbar switch circuits 100A, 100B, and 100C can be implemented as embedded blocks made up of configurable logic circuits (i.e., soft logic).

The portion 200 of the configurable IC shown in FIG. 2 has rows of routing, such as horizontal routing channels 211, and columns of routing, such as vertical routing channels 212. The configurable logic circuits 221, multi-port memory circuits 222, and other embedded features, such as digital signal processing (DSP) circuit blocks, are between the rows and columns of routing channels 211-212 and are coupled together during configuration using the routing channels 211-212.

One example of an arrangement includes a group of 40 rows and 50 columns of configurable logic circuits, memory circuits, and DSP circuit blocks with vertical and horizontal routing channels in between each row and column. The crossbar switch circuits 100 can be at either end of this exemplary arrangement. The crossbar switch circuits 100 can span the entire set of rows, or crossbar switch circuits 100 can span a subset of the rows. For example, a first 16-row crossbar switch circuit, supporting 32 bits of data, can be used to transmit the data, and a second 16-row crossbar switch circuit can be directly above the first 16-row crossbar switch circuit in the same group of rows and columns for transmitting additional data.

As another example, crossbar switch circuits 100A-100C can be used to implement a 16-bit high multi-port memory circuit. According to this example, the input and output data crossbar switch circuits alone save 6000 adaptive logic modules (ALMs). Because there may be two such structures in a group, one on top of another, a total of 12,000 ALMs of logic circuits can be saved in this example. The entire group may contain 16,000 ALMs of soft logic. By dedicating two columns of the 50 columns (in other words 4% of the area), the effective capability of the configurable IC is almost doubled, assuming enough applications can be mapped to the crossbar switch circuits.

In the example of FIG. 2, the crossbar switch circuits 100A and 100B-100C are placed at either end of the group of rows and columns to allow for different sizes of the memory circuits 222 and other memory circuits in the group to be combined to create larger memories. The arrangement of the crossbar switch circuits of FIG. 2 also saves significant routing resources, allowing the soft logic inside the group to be accessed and used by other parts of the circuit design for the configurable IC. As an example, only 32 wires of each horizontal routing channel 211 can be used to route to the crossbar switch circuits 100A-100C, with none of the wires in the vertical routing channels 212 being needed for routing to the crossbar switch circuits 100A-100C. Each of the crossbar switch circuits 100A-100C can have, as an example, a single dedicated vertical routing channel.

According to other examples, multiple smaller crossbar switch circuits can be used to build larger crossbar switch circuits. In these examples, the smaller wiring requirements for smaller crossbar switch circuits may make a group of configurable logic circuits in the IC easier to construct. According to a specific example that is not intended to be limiting, a 16-input crossbar switch circuit for 32-bit busses can be built in a single column using 16×32 =512 vertical wires. Alternately, this structure can be decomposed into two 16-input crossbar switch circuits with 16-bit busses. Soft logic is not required to combine the functionality of the two crossbar switch circuits. The difference in performance of the crossbar switch circuits is due to the different propagation delays, because of the different positions along the horizontal wiring tracks is negligible, and does not have any impact in relation to the performance of the system in the IC, which is limited by the clock tree in the IC.

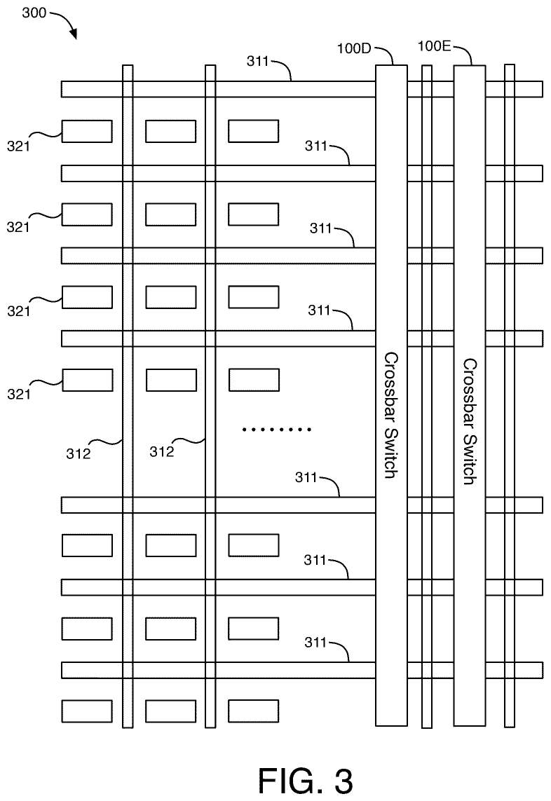

FIG. 3 is a diagram that illustrates another example of a portion 300 of a configurable integrated circuit (IC) that includes 2 crossbar switch circuits 100D and 100E. The portion 300 (e.g., sector or region) of the configurable IC shown in FIG. 3 includes configurable logic circuits 321 (shown in 3 columns as an example), horizontal routing channels 311, and vertical routing channels 312. Each of the crossbar switch circuits 100D and 100E shown in FIG. 3 can, as examples, include an instance of the crossbar switch circuit 100 of FIG. 1 or a crossbar switch circuit with any number of multiplexer circuits and input busses.

The crossbar switch circuits 100D and 100E can transmit signals between configurable logic circuits 321 and other embedded circuits in the IC using other routing in the IC, such as horizontal routing channels 311 and vertical routing channels 312. For example, the crossbar switch circuits 100D and 100E can be coupled to the horizontal routing channels 311 to transmit signals between the configurable logic circuits 321 and the other embedded circuits.

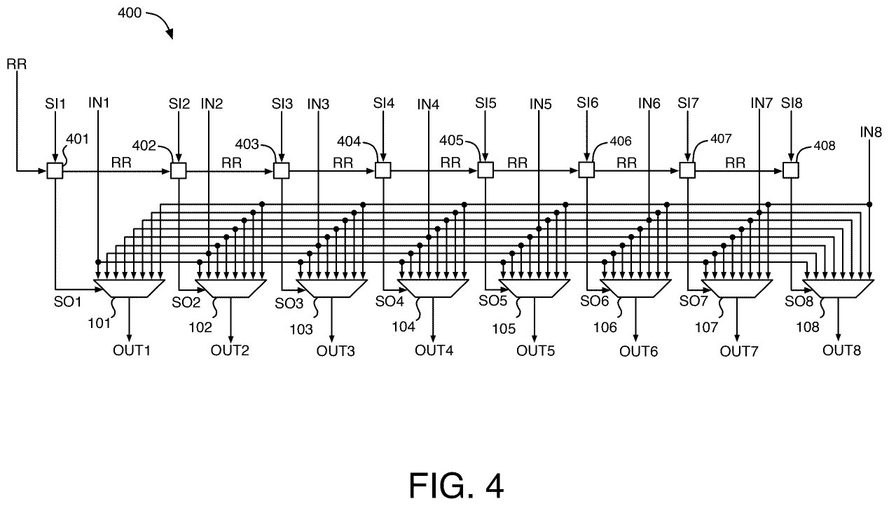

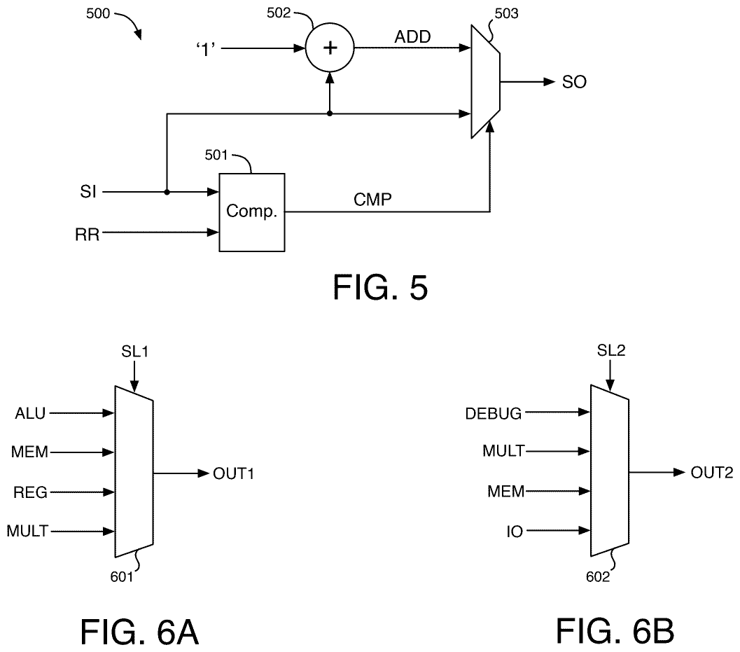

To support redundancy in a configurable IC, a row or column of configurable logic circuits in the configurable IC containing a defect can be bypassed. According to additional examples disclosed herein, the crossbar switch circuit 100 of FIG. 1 can include additional circuitry that supports redundancy, as disclosed herein below, for example, with respect to FIGS. 4-5. The multiplexer circuits in a crossbar switch circuit can be used to shift inputs and outputs of adjacent rows or columns of configurable logic circuits over a bypassed row or column of configurable logic circuits to support redundancy in a configurable IC.

FIG. 4 is a diagram that illustrates an example of a crossbar switch circuit 400 that can be used to implement redundancy for a row or column of configurable logic circuits in a configurable integrated circuit (IC). The crossbar switch circuit 400 of FIG. 4 includes the 8 multiplexer circuits 101-108, the 8 input busses, and 8 selection modification circuits 401-408. Each of the 8 input busses is coupled to an input of each of the 8 multiplexer circuits 101-108, as with the example shown in FIG. 1. The 8 input busses provide all 8 input signals IN1-IN8 to 8 inputs of each of the 8 multiplexer circuits 101-108, as shown in FIG. 4.

The 8 multiplexer circuits 101-108 generate 8 output signals OUT1-OUT8, respectively, at their outputs. Couplings between conductors (wires) in the input busses are shown by dots in FIG. 4. Although 8 multiplexer circuits 101-108 and 8 input busses are shown in the example of FIG. 4, it should be understood that crossbar switch circuits designed according to the principles disclosed herein can include any number M of multiplexer circuits and a corresponding number M of input busses.

According to the specific example shown in FIG. 4, a portion of a configurable IC has 7 row groups of configurable logic circuits. To support redundancy, the portion of the configurable IC includes 8 physical rows of configurable logic circuits, with one of the 8 physical rows of configurable logic circuits being bypassed if that row contains a defect according to this example. The multiplexer circuits 101-108 of FIG. 4 can function as the crossbar functional multiplexer circuits and as row redundancy multiplexer circuits, depending on the values of select signals as described below.

In the crossbar switch circuit 400, the multiplexer circuits 101-108 are configured by the 8 selection modification circuits 401-408, respectively. A redundant row (RR) control signal is provided to a first input of each of the 8 selection modification circuits 401-408 in crossbar switch circuit 400. 8 input select signals SI1, SI2, SI3, SI4, SI5, SI6, SI7, and SI8 (i.e., SI1-SI8) are provided to second inputs of the 8 selection modification circuits 401, 402, 403, 404, 405, 406, 407, and 408, respectively, as shown in FIG. 4. The 8 selection modification circuits 401, 402, 403, 404, 405, 406, 407, and 408 generate 8 output select signals SO1, SO2, SO3, SO4, SO5, SO6, SO7, and SO8, respectively, (i.e., SO1-SO8) as shown in FIG. 4, based on the input select signals SI1-SI8, respectively, and based on the RR control signal. The output select signals SO1-SO8 are provided to the select inputs of the 8 multiplexer circuits 101-108, respectively, as shown in FIG. 4.

The output select signals SO1-SO8 configure the selections of the multiplexer circuits 101-108 to generate the output signals OUT1-OUT8, respectively, using the input select signals SI1-SI8. Thus, each of the multiplexer circuits 101-108 provides the value of a selected one of its input signals IN1-IN8 to its output as the respective one of the output signals OUT1-OUT8. The selected one of the input signals IN1-IN8 is selected by each multiplexer circuit 101-108 based on the value of the respective one of the output select signals SO1-SO8.

FIG. 5 is a diagram that illustrates an example of a selection modification circuit 500. The selection modification circuit 500 is an example of the circuitry that can be in each of the 8 selection modification circuits 401-408 of FIG. 4. Thus, the crossbar switch circuit 400 can include 8 selection modification circuits 500 as circuits 401-408. The selection modification circuit 500 includes a comparator (comp.) circuit 501, an adder circuit 502, and a multiplexer circuit 503. An input select signal SI is provided to a first input of the comparator circuit 501, to a first input of the adder circuit 502, and to a first input of the multiplexer circuit 503. The redundant row (RR) control signal is provided to a second input of the comparator circuit 501. A signal indicating a value of 1 is provided to a second input of the adder circuit 502. The adder circuit 502 adds 1 to the value of the SI signal to generate an output signal ADD that is provided to a second input of the multiplexer circuit 503. The value of the ADD signal equals the value of the SI signal plus 1.

The comparator circuit 501 compares the value of the input select signal SI to the value of the RR control signal to generate a comparison signal CMP that is provided to the select input of the multiplexer circuit 503. The multiplexer circuit 503 provides either the value of the output signal ADD of the adder circuit 502 or the value of the input select signal SI to its output as the value of an output select signal SO based on the value of the comparison signal CMP. In the 8 selection modification circuits 401-408, the SI signal in FIG. 5 corresponds to the respective input select signal SI1-SI8 and the SO signal in FIG. 5 corresponds to the respective output select signal SO1-SO8.

The RR control signal indicates the row number of the row of configurable logic circuits to be bypassed in the configurable IC (e.g., a row with a defect). The RR control signal is provided to all of the selection modification circuits 401-408 in the crossbar switch circuit 400, as shown in FIG. 4. Referring to FIG. 5, if the value of the input select signal SI is less than the row number indicated by the RR control signal, then the multiplexer circuit 503 passes the value of the input select signal SI through to the output select signal SO unchanged. If the value of the input select signal SI is greater than the row number indicated by the RR control signal, then the multiplexer circuit 503 passes the value of the output signal ADD of the adder circuit 502 through to the output select signal SO. Thus, the selection modification circuit 500 increments the value of the select input signal SI by one and passes the incremented value of SI as the value of the output select signal SO if the value of signal SI is greater than the row number indicated by signal RR, causing the input signals to the row of configurable logic circuits having the row number indicated by signal RR to be bypassed to the next physical row(s) of configurable logic circuits in the IC.

In many circuit designs for configurable ICs, about half of the circuit design can be reasonably described as multiplexing. The data input sources of the multiplexer circuits are often repetitive. The crossbar switch circuits disclosed herein can be logically decomposed to support a number of different multiplexing applications.

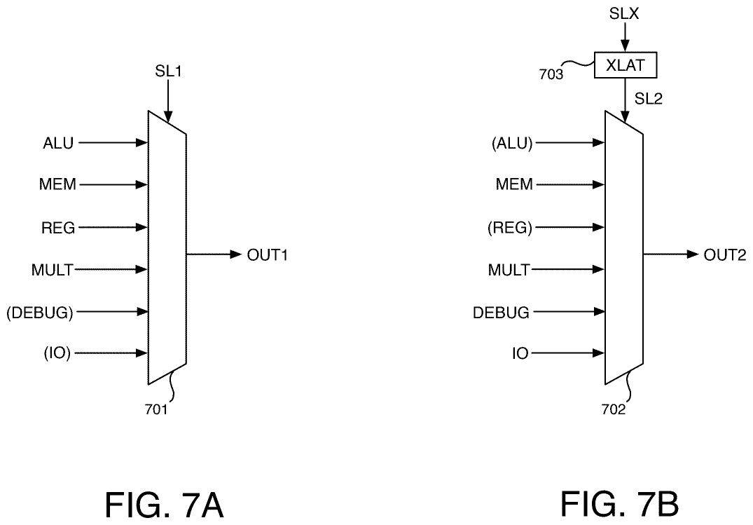

Crossbar switch circuits can be viewed as an array of multiplexers with an N number of unique select inputs, outputs, and identical input data. The identical input data can be generated, for example, to some extent by a synthesis software tool for a configurable IC. The multiplexer circuits in the crossbar switch circuits disclosed herein can be combined with synthesis processing operations for configurable ICs. In some circuit designs for configurable ICs, one or more multiplexer circuits in a circuit design for a configurable IC can be implemented by a crossbar switch circuit using the techniques disclosed herein. Examples are disclosed herein with respect to FIGS. 6A-6B and 7A-7B.

FIGS. 6A-6B illustrate examples of multiplexer circuits 601 and 602, respectively, that can be implemented by a crossbar switch circuit using the techniques disclosed herein. FIG. 6A illustrates an example of a multiplexer circuit 601 having a select input that receives a select signal SL1, 4 data inputs that receive data input signals ALU, MEM, REG, and MULT, and an output that generates an output signal OUT1 by passing the value of the data input signal selected by the select signal SL1. FIG. 6B illustrates an example of a multiplexer circuit 602 having a select input that receives a select signal SL2, 4 data inputs that receive data input signals DEBUG, MULT, MEM, and IO, and an output that generates an output signal OUT2 by passing the value of the data input signal selected by the select signal SL2. According to an example, the 2 multiplexer circuits 601 and 602 can be implemented by a single crossbar switch circuit (e.g., having 6 data input busses and 6 multiplexer circuits) using the techniques disclosed herein.

FIGS. 7A-7B are diagrams that illustrate additional examples of multiplexer circuits 701 and 702, respectively, that can be implemented by a crossbar switch circuit using the techniques disclosed herein. FIG. 7A illustrates an example of a multiplexer circuit 701 having a select input that receives a select signal SL1, 6 data inputs that receive 6 data input signals ALU, MEM, REG, MULT, (DEBUG), and (IO), and an output that generates an output signal OUT1 by passing the value of the data input signal selected by the select signal SL1.

FIG. 7B illustrates an example of a multiplexer circuit 702 having a select input that receives a select signal SL2, 6 data inputs that receive 6 data input signals (ALU), MEM, (REG), MULT, DEBUG, and IO, and an output that generates an output signal OUT2 by passing the value of the data input signal selected by the select signal SL2. The data signals in parentheticals (DEBUG), (IO), (ALU), and (REG) in FIGS. 7A-7B indicate unused data input signals. FIG. 7B also shows a translation function (XLAT) 703 that changes the select encoding to accommodate a change in selection (indexing) for the multiplexer circuit 702, as described below.

As an example, a crossbar switch circuit (e.g., crossbar switch circuit 100 or 400) can have six or more input busses and 6 or more multiplexer circuits to implement the two 4-input multiplexer circuits 701-702, each having two unused data input signals. The multiplexer circuits 701-702 have common data input signals, including MEM and MULT at different select indices, which can be implemented with common input routing wires. The multiplexer circuits 701-702 each receive two additional signals that are unused and noted in parenthesis in FIGS. 7A-7B.

The output of the first multiplexer circuit 701 is unchanged by any modification to the selection provided by select signal SL1. The bottom 4 inputs for multiplexer circuits 701 and 702 corresponding to 2 select bits are matching for the data input signals to the crossbar switch circuit. The output OUT2 of the second multiplexer circuit 702 is affected by a change to the select signal SL2 caused by translation function 703 (e.g., performed by configurable soft logic circuitry or hard logic circuitry) that is responsive to a request SLX to change the selection of the multiplexer circuit 702. The translation function 703 can, for example, receive a request SLX for the selection of the multiplexer circuit 702 to be changed from input MEM on the second input channel to input MULT on the fourth input channel. These types of translations (e.g., for up to 64 inputs for 6 select input lines) can be implemented in a single 6-input adaptive logic module (ALM) or lookup table (LUT) circuit.

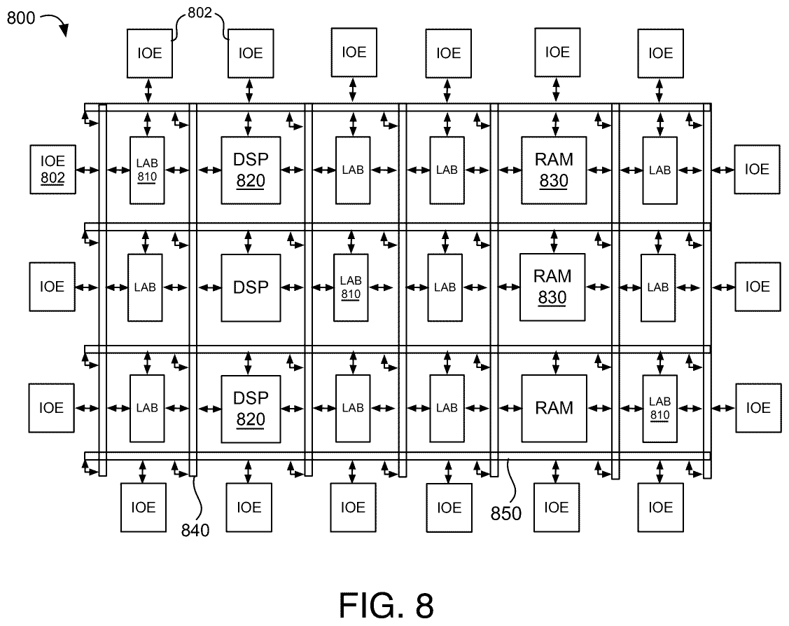

FIG. 8 is a diagram of an illustrative example of a configurable integrated circuit (IC) 800. Configurable IC 800 is an example of an IC that can include one or more crossbar switch circuits as disclosed herein with respect to FIGS. 1-7B. As shown in FIG. 8, the configurable integrated circuit 800 includes a two-dimensional array of configurable logic circuit blocks, including logic array blocks (LABs) 810 and other configurable logic circuit blocks, such as random access memory (RAM) blocks 830 and digital signal processing (DSP) blocks 820, for example. Configurable logic circuit blocks, such as LABs 810, can include smaller configurable regions (e.g., configurable logic elements, configurable logic blocks, or adaptive logic modules (ALMs)) that receive input signals and perform custom functions on the input signals to produce output signals.

The configurable integrated circuit 800 also includes programmable interconnect circuitry in the form of vertical routing channels 840 (i.e., interconnects formed along a vertical axis of configurable integrated circuit 800) and horizontal routing channels 850 (i.e., interconnects formed along a horizontal axis of configurable integrated circuit 800), each routing channel including at least one track to route at least one wire. One or more of the routing channels 840 and/or 850 can be part of a network-on-chip (NOC) having router circuits.

In addition, the configurable integrated circuit 800 has input/output elements (IOEs) 802 (e.g., including IO circuit blocks) for driving signals off of configurable integrated circuit 800 and for receiving signals from other devices. Input/output elements 802 can include parallel input/output circuitry, serial data transceiver circuitry, differential receiver and transmitter circuitry, or other circuitry used to connect one integrated circuit to another integrated circuit. Input/output elements 802 can include general purpose input/output (GPIO) circuitry (e.g., on the top and bottoms edges of IC 800), high-speed input/output (HSIO) circuitry (e.g., on the left edge of IC 800), and on-package input/output (OPIOs) circuitry (e.g., on the right edge of IC 800).

As shown, input/output elements 802 can be located around the periphery of the IC. If desired, the configurable integrated circuit 800 can have input/output elements 802 arranged in different ways. For example, input/output elements 802 can form one or more columns of input/output elements that can be located anywhere on the configurable integrated circuit 800 (e.g., distributed evenly across the width of the configurable integrated circuit). If desired, input/output elements 802 can form one or more rows of input/output elements (e.g., distributed across the height of the configurable integrated circuit). Alternatively, input/output elements 802 can form islands of input/output elements that can be distributed over the surface of the configurable integrated circuit 800 or clustered in selected areas.

Note that other routing topologies, besides the topology of the interconnect circuitry depicted in FIG. 8, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 800, fractional global wires such as wires that span part of configurable integrated circuit 800, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 800 can also contain programmable memory elements. The memory elements can be loaded with configuration data (also called programming data) using input/output elements (IOEs) 802. Once loaded, the memory elements each provide a corresponding static control signal that controls the operation of an associated functional block (e.g., LABs 810, DSP 820, RAM 830, or input/output elements 802).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 800 can include configuration memory that is organized in sectors, whereby a sector can include the configuration bits that specify the function and/or interconnections of the subcomponents and wires in or crossing that sector. Each sector can include separate data and address registers.

The configurable IC 800 of FIG. 8 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

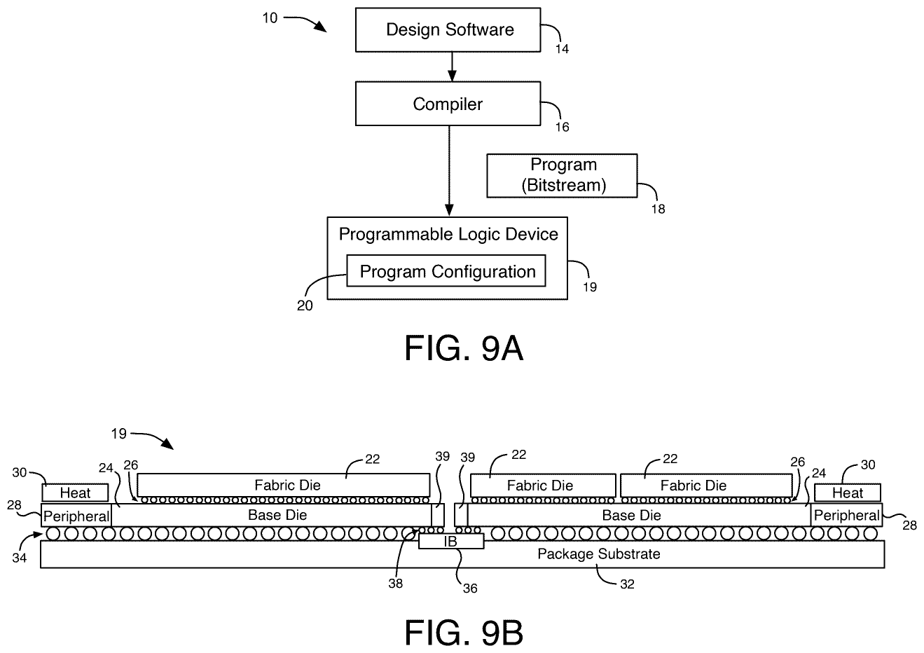

FIG. 9A illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 9B, but many others can be used, and it should be understood that this disclosure is intended to encompass any suitable programmable logic device where programmable logic fabric and fabric support circuitry are at least partially separated on different integrated circuit die.

FIG. 9B is a diagram that depicts an example of the programmable logic device 19 that includes three fabric die 22 and two base die 24 that are connected to one another via microbumps 26. In the example of FIG. 9B, at least some of the programmable logic fabric of the programmable logic device 19 is in the three fabric die 22, and at least some of the fabric support circuitry that operates the programmable logic fabric is in the two base die 24. For example, some of the circuitry of configurable IC 800 shown in FIG. 8 (e.g., LABs 810, DSP 820, and RAM 830) can be located in the fabric die 22 and some of the circuitry of IC 800 (e.g., input/output elements 802) can be located in the base die 24.

Although the fabric die 22 and base die 24 appear in a one-to-one relationship or a two-to-one relationship in FIG. 9B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 9B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

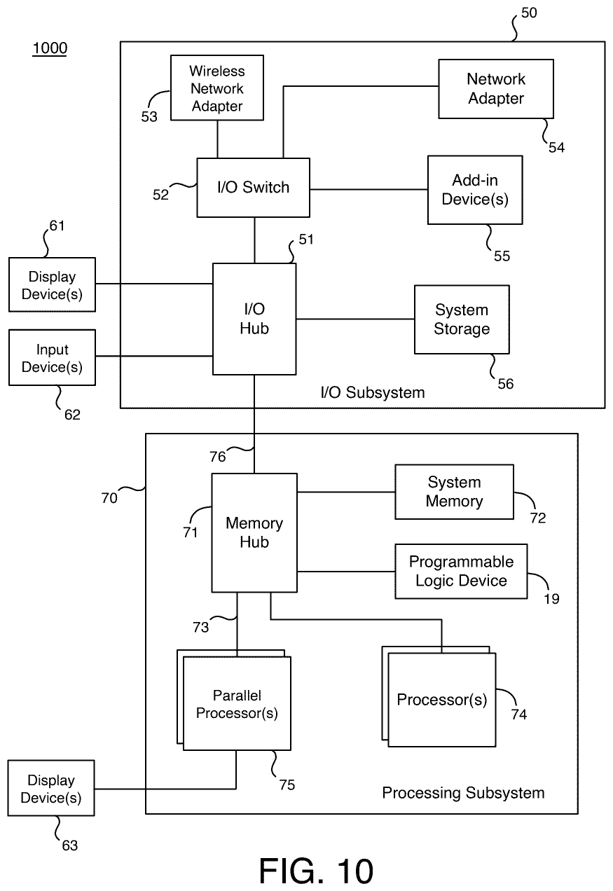

FIG. 10 is a block diagram illustrating a computing system 1000 configured to implement one or more aspects of the embodiments described herein. The computing system 1000 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 1000 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 1000. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 1000 can include other components not shown in FIG. 10, including other port connections, optical storage drives, video capture devices, and the like, that can also be connected to the I/O hub 51. Communication paths interconnecting the various components in FIG. 10 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 1000 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 1000 can be integrated into a single package to form a system in package (SIP) configuration. In one embodiment, at least a portion of the components of the computing system 1000 can be integrated into a multi-chip module (MCM), which can be interconnected with other multi-chip modules into a modular computing system.

The computing system 1000 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 1000. For example, any number of add-in cards or peripherals can be supported, or some components can be eliminated. Furthermore, some architectures can use different terminology for components similar to those illustrated in FIG. 10. For example, the memory hub 71 can be referred to as a Northbridge in some architectures, while the I/O hub 51 can be referred to as a Southbridge.

Additional examples are now described. Example 1 is a configurable integrated circuit comprising: first logic circuits; second logic circuits; and a first crossbar switch circuit comprising first multiplexer circuits and first input busses coupled to the first multiplexer circuits, wherein first inputs of each of the first multiplexer circuits are coupled to each of the first input busses, wherein the configurable integrated circuit is configurable to provide first input signals generated by the first logic circuits to the first inputs of each of the first multiplexer circuits through the first input busses, and wherein the first multiplexer circuits are configurable to provide first values of the first input signals that are received through the first input busses to the second logic circuits.

In Example 2, the configurable integrated circuit of Example 1, wherein the first logic circuits comprise first lookup table circuits, wherein the second logic circuits comprise second lookup table circuits, and wherein the first multiplexer circuits are configurable to provide the first values of the first input signals received from the first lookup table circuits through the first input busses to the second lookup table circuits.

In Example 3, the configurable integrated circuit of any one of Examples 1-2, wherein the first logic circuits comprise first configurable memory circuits, wherein the second logic circuits comprise second configurable memory circuits, and wherein the first multiplexer circuits are configurable to provide the first values of the first input signals received from the first configurable memory circuits through the first input busses to the second configurable memory circuits.

In Example 4, the configurable integrated circuit of any one of Examples 1-3 may optionally include, wherein the first crossbar switch circuit further comprises selection modification circuits that are configurable to adjust first select signals to the first multiplexer circuits to cause the first multiplexer circuits to bypass a row or column of third logic circuits.

In Example 5, the configurable integrated circuit of Example 4 may optionally include, wherein each of the selection modification circuits comprises a comparator circuit that compares a second select signal to a number of the row or column of the third logic circuits to generate a comparison output and a second multiplexer circuit that causes one of the first select signals to equal the second select signal or an incremented signal based on the comparison output.

In Example 6, the configurable integrated circuit of any one of Examples 1-5 further comprises: a second crossbar switch circuit comprising second multiplexer circuits and second input busses coupled to the second multiplexer circuits, wherein second inputs of each of the second multiplexer circuits are coupled to each of the second input busses, wherein the configurable integrated circuit is configurable to provide second input signals generated by the second logic circuits to the second inputs of each of the second multiplexer circuits through the second input busses, and wherein the second multiplexer circuits are configurable to provide second values of the second input signals that are received through the second input busses to third logic circuits.

In Example 7, the configurable integrated circuit of any one of Examples 1-6 may optionally include, wherein the first crossbar switch circuit is configurable to implement a second multiplexer circuit and a third multiplexer circuit in a circuit design for the integrated circuit.

In Example 8, the configurable integrated circuit of any one of Examples 1-7 may optionally include, wherein the configurable integrated circuit further comprises third logic circuits that are configurable to be coupled together to form larger circuit structures, and wherein the first crossbar switch circuit is configurable to route signals to or from the third logic circuits.

In Example 9, the configurable integrated circuit of any one of Examples 1-8 may optionally include, wherein the first input busses in the first crossbar switch circuit are hardwired couplings to the first inputs of each of the first multiplexer circuits that are non-configurable.

Example 10 is a method for transmitting first signals between first logic circuits and second logic circuits in a configurable integrated circuit, the method comprising: providing the first signals from the first logic circuits to first multiplexer circuits through input busses, wherein a crossbar switch circuit in the configurable integrated circuit comprises the first multiplexer circuits and the input busses, and wherein inputs of each of the first multiplexer circuits are coupled to each of the input busses; and providing values of the first signals from the input busses through the first multiplexer circuits in the crossbar switch circuit to the second logic circuits.

In Example 11, the method of Example 10 further comprises: configuring the first multiplexer circuits to select the values of the first signals using select signals generated by selection modification circuits.

In Example 12, the method of any one of Examples 10-11, wherein providing the values of the first signals from the input busses through the first multiplexer circuits in the crossbar switch circuit to the second logic circuits further comprises providing the values of the first signals from the input busses through the first multiplexer circuits to configurable memory circuits or lookup table circuits in the second logic circuits.

In Example 13, the method of any one of Examples 10-12 further comprises: selecting an incremented value of a first select signal as a second select signal based on a comparison between the first select signal and a number of a row or column of third logic circuits in the configurable integrated circuit; and configuring one of the first multiplexer circuits to select one of the values of the first signals using the second select signal to bypass the row or column of the third logic circuits.

In Example 14, the method of any one of Examples 10-13 further comprises: configuring the first multiplexer circuits to implement a second multiplexer circuit and a third multiplexer circuit in a circuit design for the configurable integrated circuit.

In Example 15, the method of any one of Examples 10-14 may optionally include, wherein the input busses in the crossbar switch circuit are hardwired couplings to the inputs of each of the first multiplexer circuits that are non-configurable, and wherein each of the first signals is provided through one of the input busses to one of the inputs of each of the first multiplexer circuits.

Example 16 is a non-transitory computer readable storage medium comprising instructions stored thereon that, when executed by a configurable integrated circuit, cause the configurable integrated circuit to: configure first logic circuits in the configurable integrated circuit to provide signals through input busses to inputs of multiplexer circuits in a crossbar switch circuit in the configurable integrated circuit, wherein the inputs of each of the multiplexer circuits are coupled to each of the input busses; and configure the multiplexer circuits to provide values of the signals to second logic circuits in the configurable integrated circuit.

In Example 17, the non-transitory computer readable storage medium of Example 16 may optionally include, wherein the instructions further cause the configurable integrated circuit to: configure first lookup table circuits in the first logic circuits to generate the signals; and configure the multiplexer circuits to provide the values of the signals to second lookup table circuits in the second logic circuits.

In Example 18, the non-transitory computer readable storage medium of any one of Examples 16-17 may optionally include, wherein the instructions further cause the configurable integrated circuit to: configure first configurable memory circuits in the first logic circuits to generate the signals; and configure the multiplexer circuits to provide the values of the signals to second configurable memory circuits in the second logic circuits.

In Example 19, the non-transitory computer readable storage medium of any one of Examples 16-18 may optionally include, wherein the instructions further cause the configurable integrated circuit to: configure the multiplexer circuits to provide the values of the signals to configurable memory circuits or lookup table circuits in the second logic circuits.

In Example 20, the non-transitory computer readable storage medium of any one of Examples 16-19 may optionally include, wherein the input busses in the crossbar switch circuit are hardwired couplings to the inputs of each of the multiplexer circuits that are non-configurable.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A configurable integrated circuit comprising:
first logic circuits;
second logic circuits; and
a first crossbar switch circuit comprising first multiplexer circuits and first input busses coupled to the first multiplexer circuits, wherein first inputs of each of the first multiplexer circuits are coupled to each of the first input busses, wherein the configurable integrated circuit is configurable to provide first input signals generated by the first logic circuits to the first inputs of each of the first multiplexer circuits through the first input busses, and wherein the first multiplexer circuits are configurable to provide first values of the first input signals that are received through the first input busses to the second logic circuits.

2. The configurable integrated circuit of claim 1, wherein the first logic circuits comprise first lookup table circuits, wherein the second logic circuits comprise second lookup table circuits, and wherein the first multiplexer circuits are configurable to provide the first values of the first input signals received from the first lookup table circuits through the first input busses to the second lookup table circuits.

3. The configurable integrated circuit of claim 1, wherein the first logic circuits comprise first configurable memory circuits, wherein the second logic circuits comprise second configurable memory circuits, and wherein the first multiplexer circuits are configurable to provide the first values of the first input signals received from the first configurable memory circuits through the first input busses to the second configurable memory circuits.

4. The configurable integrated circuit of claim 1, wherein the first crossbar switch circuit further comprises selection modification circuits that are configurable to adjust first select signals to the first multiplexer circuits to cause the first multiplexer circuits to bypass a row or column of third logic circuits.

5. The configurable integrated circuit of claim 4, wherein each of the selection modification circuits comprises a comparator circuit that compares a second select signal to a number of the row or column of the third logic circuits to generate a comparison output and a second multiplexer circuit that causes one of the first select signals to equal the second select signal or an incremented signal based on the comparison output.

6. The configurable integrated circuit of claim 1 further comprising:
a second crossbar switch circuit comprising second multiplexer circuits and second input busses coupled to the second multiplexer circuits, wherein second inputs of each of the second multiplexer circuits are coupled to each of the second input busses, wherein the configurable integrated circuit is configurable to provide second input signals generated by the second logic circuits to the second inputs of each of the second multiplexer circuits through the second input busses, and wherein the second multiplexer circuits are configurable to provide second values of the second input signals that are received through the second input busses to third logic circuits.

7. The configurable integrated circuit of claim 1, wherein the first crossbar switch circuit is configurable to implement a second multiplexer circuit and a third multiplexer circuit in a circuit design for the integrated circuit.

8. The configurable integrated circuit of claim 1 further comprising:
third logic circuits that are configurable to be coupled together to form larger circuit structures, wherein the first crossbar switch circuit is configurable to route signals to or from the third logic circuits.

9. The configurable integrated circuit of claim 1, wherein the first input busses in the first crossbar switch circuit are hardwired couplings to the first inputs of each of the first multiplexer circuits that are non-configurable.

10. A method for transmitting first signals between first logic circuits and second logic circuits in a configurable integrated circuit, the method comprising:
providing the first signals from the first logic circuits to first multiplexer circuits through input busses, wherein a crossbar switch circuit in the configurable integrated circuit comprises the first multiplexer circuits and the input busses, and wherein inputs of each of the first multiplexer circuits are coupled to each of the input busses; and
providing values of the first signals from the input busses through the first multiplexer circuits in the crossbar switch circuit to the second logic circuits.

11. The method of claim 10 further comprising:
configuring the first multiplexer circuits to select the values of the first signals using select signals generated by selection modification circuits.

12. The method of claim 10, wherein providing the values of the first signals from the input busses through the first multiplexer circuits in the crossbar switch circuit to the second logic circuits further comprises providing the values of the first signals from the input busses through the first multiplexer circuits to configurable memory circuits or lookup table circuits in the second logic circuits.

13. The method of claim 10 further comprising:
selecting an incremented value of a first select signal as a second select signal based on a comparison between the first select signal and a number of a row or column of third logic circuits in the configurable integrated circuit; and
configuring one of the first multiplexer circuits to select one of the values of the first signals using the second select signal to bypass the row or column of the third logic circuits.

14. The method of claim 10 further comprising:
configuring the first multiplexer circuits to implement a second multiplexer circuit and a third multiplexer circuit in a circuit design for the configurable integrated circuit.

15. The method of claim 10, wherein the input busses in the crossbar switch circuit are hardwired couplings to the inputs of each of the first multiplexer circuits that are non-configurable, and wherein each of the first signals is provided through one of the input busses to one of the inputs of each of the first multiplexer circuits.

16. A non-transitory computer readable storage medium comprising instructions stored thereon that, when executed by a configurable integrated circuit, cause the configurable integrated circuit to:
configure first logic circuits in the configurable integrated circuit to provide signals through input busses to inputs of multiplexer circuits in a crossbar switch circuit in the configurable integrated circuit, wherein the inputs of each of the multiplexer circuits are coupled to each of the input busses; and
configure the multiplexer circuits to provide values of the signals to second logic circuits in the configurable integrated circuit.

17. The non-transitory computer readable storage medium of claim 16, wherein the instructions further cause the configurable integrated circuit to:
configure first lookup table circuits in the first logic circuits to generate the signals; and
configure the multiplexer circuits to provide the values of the signals to second lookup table circuits in the second logic circuits.

18. The non-transitory computer readable storage medium of claim 16, wherein the instructions further cause the configurable integrated circuit to:
configure first configurable memory circuits in the first logic circuits to generate the signals; and
configure the multiplexer circuits to provide the values of the signals to second configurable memory circuits in the second logic circuits.

19. The non-transitory computer readable storage medium of claim 16, wherein the instructions further cause the configurable integrated circuit to:
configure the multiplexer circuits to provide the values of the signals to configurable memory circuits or lookup table circuits in the second logic circuits.

20. The non-transitory computer readable storage medium of claim 16, wherein the input busses in the crossbar switch circuit are hardwired couplings to the inputs of each of the multiplexer circuits that are non-configurable.
